(19) United States
(12) Patent Application Publication
(10) Pub. No.: US 2018/0122417 A1
(43) Pub. Date: May 3, 2018

(54) MAGNETIC RECORDING MEDIUM

(71) Applicant: KABUSHIKI KAISHA TOSHIBA, Tokyo (JP)

(72) Inventors: Akira WATANABE, Kawasaki Kanagawa (JP); Tomoki UMETSU, Ota Tokyo (JP); Tsuyoshi ONITSUKA, Yokohama Kanagawa (JP); Hiroyuki HYODO, Yokohama Kanagawa (JP)

(21) Appl. No.: 15/445,840

(22) Filed: Feb. 28, 2017

(30) Foreign Application Priority Data
Oct. 28, 2016 (JP) 2016-211529

(51) Int. Cl. G11B 5/73; C23C 14/16; G11B 5/64; G11B 5/738; G11B 5/82; G11B 5/851

(52) U.S. Cl. CPC G11B 5/7315; C23C 14/165; G11B 5/851; G11B 5/738; G11B 5/825; G11B 5/64

(57) ABSTRACT

A magnetic recording medium includes a substrate and a stacked film on the substrate and including a magnetic recording layer. An elastic modulus E_{sub} of the substrate satisfies Equation (1) below, where h is a film thickness of the stacked film and E_{film} is an Young's modulus of the stacked film:

E_{sub}≤(200*E_{film})/(6*h) (1).

This application is based upon and claims the benefit of priority from Japanese Patent Application No. 2016-211529, filed Oct. 28, 2016, the entire contents of which are incorporated herein by reference.

### FIELD

Embodiments described herein relate generally to a magnetic recording medium.

### BACKGROUND

To improve resistance to superficial scratching on a magnetic recording medium due to contact between the magnetic recording medium and a magnetic head, a method of adjusting the mechanical characteristics, such as a Young's modulus and yield stress, of each layer of the magnetic recording medium is generally used.

The related art, as a way to improve scratch resistance, employs technologies for causing the yield stress of each layer to be equal to or less than that of a vertical magnetic recording layer, while causing Young's modulus of a Soft Under Layer SUL to be equal to or greater than that of the vertical magnetic recording layer. Here, it is assumed that plastic deformation of the vertical magnetic recording layer can be prevented by employing the SUL layer. However, when a stress applied to the magnetic recording layer is equal to or greater than the yield stress of the vertical magnetic recording layer, plastic deformation of the vertical magnetic recording layer may occur irrespective of presence or absence of yield of the SUL layer. In addition, the yield stress of the vertical magnetic recording layer is reduced as the sizes of magnetic particles of the magnetic recording layer become smaller to achieve high density. Therefore, plastic deformation of the magnetic recording layer may occur even for smaller stresses.

Accordingly, there is a technology for improving plastic deformation of a magnetic recording layer by inserting a deformation layer into the middle of the magnetic recording layer as a way to decrease a plastic deformation amount of the magnetic recording layer even when a load equal to or greater than its yield stress is applied to the magnetic recording layer. However, since the deformation layer is inserted into the middle of the magnetic recording layer, magnetostatic characteristics can be affected considerably so that a recording density capacity is deteriorated.

In view of such a circumstance, it is desirable to provide a magnetic recording medium in which stress applied to a magnetic recording layer is reduced and scratch resistance is improved without damaging its magnetic recording characteristics.

### DESCRIPTION OF THE DRAWINGS

FIG. 1 is a sectional view illustrating a configuration of an example of a magnetic recording medium according to an embodiment.

FIG. 2 is a sectional view illustrating a configuration of an example of the magnetic recording medium according to the embodiment.

FIG. 3 is a sectional view illustrating a configuration of an example of the magnetic recording medium according to the embodiment.

FIG. 4 is a sectional view illustrating a configuration of an example of the magnetic recording medium according to the embodiment.

FIG. 5 is a graph illustrating a relationship between a driving time of the magnetic recording medium according to the embodiment and an error rate.

FIG. 6 is a graph illustrating a relationship between a film thickness of the magnetic recording medium according to the embodiment and a signal attenuation rate.

FIG. 7 is a graph illustrating a relationship between a slope of a signal attenuation rate with respect to film thickness of the magnetic recording medium according to the embodiment and an elastic modulus of a substrate.

FIG. 8 is a graph illustrating results of a long-term reliability test conducted on the magnetic recording medium according to the embodiment.

FIG. 9 is a graph illustrating the NRRO observed during a long-term reliability test for each of different magnetic recording media.

FIG. 10 is a graph illustrating error rates during the long-term reliability test for each of different magnetic recording media.

### DETAILED DESCRIPTION

Embodiments provide a magnetic recording medium with good scratch resistance.

In general, according to one embodiment, there is provided a magnetic recording medium including: a substrate; and a stacked film that is formed on the substrate and includes a magnetic recording layer. An Young's modulus E_{sub} (GPa) of the substrate satisfies a relation expressed in Expression (1) below when h (nm) is a film thickness of the stacked film and E_{film} (GPa) is an Young's modulus of the stacked film.

E_{sub}≤(200*E_{film})/(6*h) (1)

According to an embodiment, a magnetic recording medium includes: a substrate; and a stacked film that is formed on the substrate and includes a magnetic recording layer. An Young's modulus E_{sub} (GPa) of the substrate satisfies a relation expressed in Equation (1) below where h (nm) is a film thickness of the stacked film and E_{film} (GPa) is an Young's modulus of the stacked film.

E_{sub}≤(200*E_{film})/(6*h) (1)

In the magnetic recording medium according to the embodiment, as expressed in Equation (1) above, in regard to the Young's modulus of the stacked film on the substrate, E_{film}, and a film thickness of the stacked film, h, a substrate that has an Young's modulus equal to or less than the value (200*E_{film})/(6*h) is used, so that a stress field occurring due to contact between the substrate and the magnetic recording head can be released to the substrate. Thus, it is possible to provide the magnetic recording medium with high crack resistance.

According to the embodiment, by changing only the substrate, it is possible to improve crack resistance of the magnetic recording medium without damaging the characteristics of each stacked film that are necessary to increase a recording density.

The Young's modulus used in Equation (1) above can be measured as follows.

### Method of Measuring Young's Modulus

In the evaluation of an Young's modulus, a nano-indentation method was used for measurement. For the measurement, Tribo Indenter made by Hysitron Inc. was used and a Berkovich indenter was employed to perform evaluation of a single indentation measurement. As an evaluation sample, a sample in which a single film with a film thickness of about 40 nm was formed on an aluminum substrate in accordance with a sputtering method, was used. An elastic modulus was evaluated from the Hertz contact theory expressed in Equation (2) below.

$${E}_{r} = \frac{3 P}{4} \sqrt{\frac{1}{{Rd}^{3}}} \qquad ( 2 )$$

Here, P is an indentation load (N), R is a radius (m) of a spherical indenter, d is an indentation depth (mm), Er is a composite elastic modulus (Mpa). In addition, Er is expressed in Equation (3) below using an elastic modulus Es (MPa) of the sample, an elastic modulus E* (MPa) of the diamond indenter, a Poisson's ratio νs of the sample, and a Poisson's ratio ν* of the diamond indenter.

$$\frac{1}{{E}_{r}} = \frac{1 - {ν}_{s}^{2}}{{E}_{s}} + \frac{1 - {ν}^{* 2}}{{E}^{*}} \qquad ( 3 )$$

### Flexure Test

As an elastic modulus of a substrate, there is a flexural elastic modulus which is evaluated during a flexure test in addition to an Young's modulus measured by the foregoing indentation. To evaluate a flexural elastic modulus, a 5566 type apparatus made by Instron Inc. can be used. A flexural elastic modulus was measured by following JIS K7074, ASTM D790. Specifically, there is a method of calculating a flexural elastic modulus from an initial gradient of a straight line of a deflection curve and a flexural load. A flexural elastic modulus Eb (MPa) is given by Equation (4) below.

$${E}_{b} = \frac{{L}^{3}}{4 {bh}^{3}} * \frac{P}{δ} \qquad ( 4 )$$

Here, L is an inter-point distance (mm), b is a test piece width (mm), h is a test piece thickness (mm), P is a load (N), and δ is a stroke (mm).

### Magnetic Recording Medium

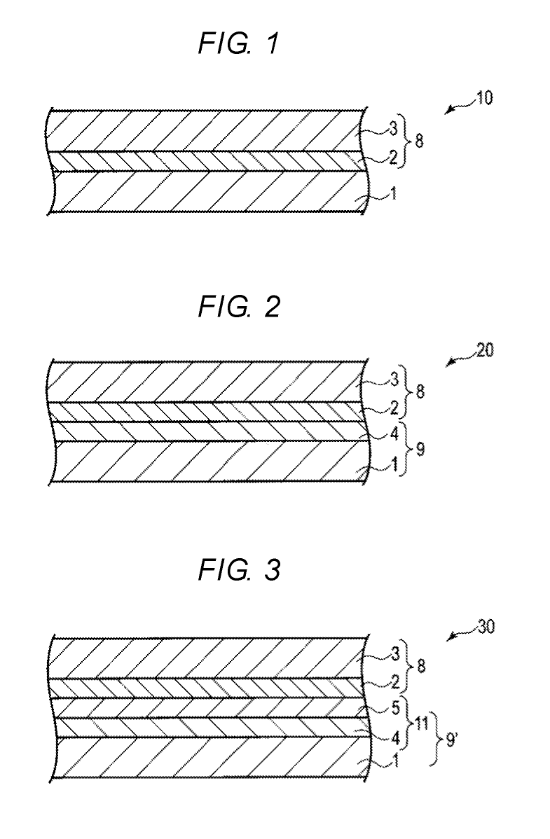

FIG. 1 is a sectional view illustrating a configuration of an example of a magnetic recording medium according to an embodiment

As illustrated, a magnetic recording medium 10 includes a substrate 1 and a stacked body 8 formed on the substrate 1. The stacked body 8 includes an underlying layer 2 and a magnetic recording layer 3 formed on the underlying layer 2.

Next, a material proper for each layer of the magnetic recording medium will be described.

As the substrate, a nonmagnetic substrate such as a glass substrate or an aluminum alloy substrate can be used. The aluminum alloy substrate used in the embodiment includes an aluminum plate and an alloy layer formed on the aluminum plate. The aluminum alloy substrate can be formed using an alloy layer or a sputtering method. In the case of a plating method, for example, plating can be performed by impregnating at least one kind of metal selected from metals of an iron group elements such as iron, nickel, cobalt, and palladium and platinum group elements in a hypophosphorous acid solution and educing a metal layer using the surface of the metal as a catalyst. The alloy layer can have a multilayer structure that includes a first plated layer formed on the substrate and a second plated layer formed on the first plated layer. A sum of the film thicknesses of the plated layers of the multilayer structure can be set to equal to or greater than 100 nm.

In the case of a sputtering, for example, a film which has aluminum as a main component can be used as an alloy layer. An aluminum layer has crystallinity. Thus, surface roughness of the aluminum layer tends to increase. As a method of suppressing the surface roughness, there is a method of applying a bias to the substrate and adding about 10 at % of Si or Ti to the substrate surface with plasma in addition to a reverse sputtering method of etching a substrate surface with plasma. An Young's modulus of a surface layer formed by a sputtering method can be controlled with pressure at the time of forming the film, the substrate temperature, or the like. When the film formation pressure is increased, the density of the formed film can be lowered and its Young's modulus can be decreased. When the substrate temperature is lowered, a kinetic energy of particles of the formed film decreases. Therefore, its elastic modulus can be lowered.

The film thickness of a film formed with a sputtering method can be set to be equal to or greater than 20 nm. As the film thickness becomes thicker, the Young's modulus of the substrate surface can be further controlled. However, the surface roughness tends to increase.

FIG. 2 is a sectional view illustrating a configuration of another example of the magnetic recording medium according to the embodiment.

As illustrated, a magnetic recording medium 20 is the same as that in FIG. 1 except that an alloy substrate 9 including substrate 1 and a first alloy layer 4 formed on the substrate 1 is used instead of the substrate 1.

FIG. 3 is a sectional view illustrating a configuration of still another example of the magnetic recording medium according to the embodiment.

As illustrated, a magnetic recording medium 30 is the same as that in FIG. 1 except that an alloy substrate 9′ including a substrate 1 and an alloy layer 11 that has a multilayer structure including a first alloy layer 4 formed on the substrate 1 and a second alloy layer 5 formed on the first alloy layer 4 is used instead of the substrate 1.

In the manufacturing of the alloy layers, a sputtering method can be used in addition to a plating method. In the case of the plating method, for example, a nickel alloy can be used as a metal used in plating. An elastic modulus can be controlled with a ratio of nickel to phosphorus. When a general ratio of nickel is about 88% to 99% and P is about 1% to 12%, an elastic modulus of layer becomes lower as a ratio of phosphorus is higher. As a metal used in the sputtering method, for example, an aluminum alloy can be used. An elastic modulus can be controlled with pressure at the time of forming a film, the sputtering speed, and the substrate temperature.

The substrate can have a flexural elastic modulus equal to or greater than 65 GPa. When the flexural elastic modulus of the substrate is less than 65 GPa, there is a tendency that mechanical characteristics may not be improved with an alloy layer and there is a tendency that a vibration element (NRR) not synchronized with rotation increases. In addition, the flexural elastic modulus of the substrate may be higher. However, in general, the mass of a material with a high flexural elastic modulus increases and the weight of the substrate increase. Therefore, there is a tendency that an error rate increases during a falling test. However, an amorphous material such as glass that has a small mass and has a flexural elastic modulus equal to or greater than 80 GPa can be used.

A stacked layer of a base material and the first alloy layer can have a flexural elastic modulus equal to or greater than 75 GPa. When the flexural elastic modulus is less than 75 GPa, a deflection amount under an external pressure of 1 kgf increases. Thus, there is a tendency that a probability of contact with a ramp portion, which is formed for a head to stand by at the time of non-operation, increases. Additionally, there is a tendency that vibration (NRRO) not synchronized with rotation increases and a capacity in a track density direction decreases.

An Young's modulus of the stacked layer of the base material and the first alloy layer can be decreased under a condition satisfying Equation (1). When the Young's modulus does not satisfy the foregoing expression, there is a tendency that an error caused by a flaw occurring on a surface will increase during a long-term reliability test.

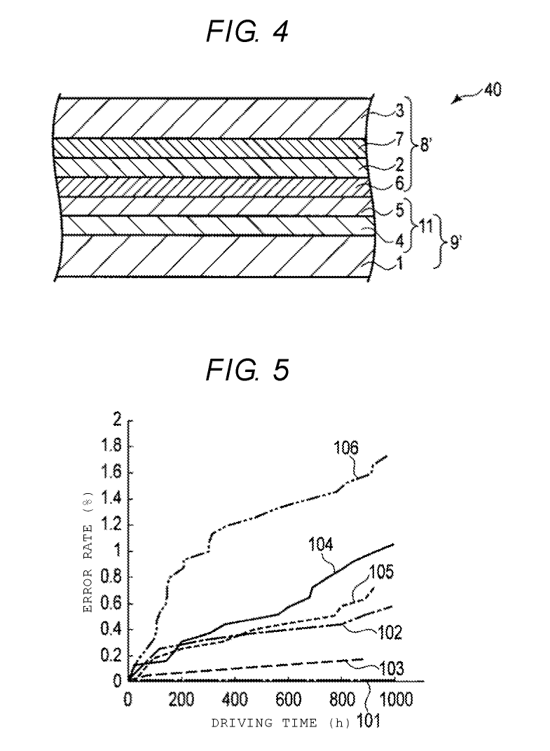

FIG. 4 is a sectional view illustrating a configuration of still another example of the magnetic recording medium according to the embodiment.

As illustrated, a magnetic recording medium 40 includes the same alloy substrate 9′ as that in FIG. 3 and a stacked body 8′ that includes a magnetic recording layer 3 formed on the alloy substrate 9′.

The stacked body 8′ includes a soft magnetic underlying layer 6 formed on the alloy substrate 9′, an underlying layer formed on the soft magnetic underlying layer 6, an intermediate layer 7 formed on the underlying layer 2, and the magnetic recording layer 3 formed on the intermediate layer 7.

As illustrated, the soft magnetic underlying layer (SUL) 6 can be formed on, for example, a substrate such as the alloy substrate 9′. As the soft magnetic underlying layer, an amorphous alloy that contains at least one kind of main component selected from Fe, Ni, Co, and Ta and an added component selected from Zr, B, and Si can be used. For example, a composition ratio of FeCo is set to 65:35, the largest saturation magnetic flux density

The underlying layer (UL) 2 that improves crystal orientation can be formed on the soft magnetic underlying layer 6. As the underlying layer that improves crystal orientation, an alloy that contains at least two kinds of metals selected from Cr, Ti, Ni, Ta, and W can be used.

The intermediate layer (IL) 7 can be formed on the underlying layer 2. As the intermediate layer, a Ru alloy can be used. Cr or the like can be added to the Ru alloy in consideration of matching lattices in in-plane directions.

The magnetic recording layer (Mag) can be formed on the intermediate layer 7. As the magnetic recording layer, for example, a continuous film and a granular film in which CoPt is a main component can be used.

Additionally, a granular film in which Fe or Tb is a main component can be used as the magnetic recording layer. In order to improve magnetostatic characteristics, an additive element such as Cr, Pt, Co, Ta, Cu, B, or Nd can be added. As a material of a non-magnetic grain boundary region of a granular film type recording layer, an oxide such as Si, Cr, or Ti can be used. Since such added grains are rarely solved with the above-described CoPt alloy, the added grains can be easily formed in a grain boundary between magnetic crystal particles and the granular film can be relatively easily obtained. A material of grain boundary may be crystalline or noncrystalline or may be a void filled with nothing.

A cap layer (not illustrated) can be formed on the magnetic recording layer. In the cap layer, a continuous film in which, for example, CoPt is a main component can be used.

A protective layer (not illustrated) can be formed on the cap layer. In the protective layer, for example, a diamond like carbon (DLC) generated by a chemical vapor deposition (CVD) can be used. A lubricant layer (not illustrated) can be formed on the surface of DLC.

Various test methods for the magnetic recording medium used in the embodiment will be described below.

### Pre-Write

First, a signal of 200 kFCI is recorded on an obtained medium. For example, by using a flaw inspection (certifier) head in which a write width is about 80 μm as a write head, overwriting is performed so that a track width is 60 μm.

### Scratch Test

Next, a scratch test for evaluation crack resistance of a medium will be described.

A scratch test is performed on a pre-written medium, as described above, using Trib Indenter TI950 made by Hysitron.

As a used indenter, a spherical indenter with a radius of curvature of 1.5 μm is used. A scratch condition is that a setting load is 500 μN and a movement distance is 10 μm using a load control mode in which a constant distance is scratched with a constant load. A scratch interval is set to 2 μm A total of 5 scratches is performed.

Thereafter, an attenuation amount of a pre-write signal of a scratch portion is measured with a magnetic force microscope (MFM) to evaluate crack resistance of a medium. It is possible to confirm that in the scratch portion, a depression is formed due to plastic deformation at the time of indentation is formed, and crystal of a magnetic recording layer is ruined and signal is attenuated due to a decrease in magnetic crystalline anisotropy. An attenuation amount of the signal is expressed by a ratio between a root mean square (RMS value) of a signal strength when scratch is present and an RMS value of a signal strength when scratch is absent. As a result obtained by inserting a medium evaluated in a scratch test into a drive and performing a long-term reliability test of 1000 hours, it is understood that there is correlation between an NG (no good) rate in a long-term reliability test and an attenuation amount of a signal evaluated with an RMS value. Here, a signal attenuation amount evaluated with an RMS value is a value that varies by a pre-write pattern density. In general, in a pattern in which a pre-write recording density is low, a diamagnetic field is strong and a signal attenuation amount of a scratch portion tends to increase. Conversely, when the recording density is high, a diamagnetic field decreases. Therefore, a signal attenuation amount of a scratch portion tends to decrease. When an attenuation rate of a signal evaluated with an RMS value exceeds 20% at a track width of 60 μm and a recording density of 200 kFCI used for evaluation, as will be described below, an NG rate exceeds 1% in the long-term reliability test of 1000 hours.

### Long-Term Reliability Test

To predict occurrence of a fault, a test for evaluation an error rate at the time of operating 1000 or more apparatuses for 1000 hours is performed. This test is referred to as a long-term reliability test. In the long-term reliability test, the following operations are performed repeatedly.

### Surface Scan Test

In a surface scan test, a reproduction test for a magnetic head, a coercive force test for a medium, and an inspection for presence or absence of a position decision fault at the time of sequential movement from an outermost circumference to an innermost circumference are performed.

### Random Seeking Test

In a random seeking test, irregular movement is performed 3000 times and presence or absence a position decision fault is observed during the test. Movement to a position designated by a random number and a test for a data reading operation are performed.

### Funnel Seeking Test

In a funnel seeking test, presence or absence of a position decision fault is inspected while moving the magnetic head by a maximum movement distance from an outermost circumference track to an innermost circumference track repeatedly 2000 times. After data reading at the outermost circumference is performed, a test for data reading of the innermost circumference is performed. A test at the time of maximum shaking of a head is performed.

### Loading or Unloading Test

In a loading or unloading test, inspection for presence or absence of a position decision fault or a reproduced signal output fault occurring at the time of loading or unloading a magnetic head on or from a medium is performed.

By repeatedly performing this test, a fault occurrence ratio for 1000 times is observed. When the fault occurrence ratio exceeds 1%, it is considered that there is a quality problem.

### Non-Repeatable Run-Out (NRRO) Evaluation

To improve the track density of a hard disk drive (HDD), position decision precision of a head serves as a considerably important role. The position decision precision of a head is considerably influenced by a servo technology, but an influence of vibration of a spindle motor or a medium on a mechanical component is considerably large. In general, vibration is classified into two types, repeatable run out (RRO) and non-repeatable run out (NRRO). The former is a component synchronized with rotation and the latter is a component not synchronized with rotation. Vibration occurring due to rigidity or the like of a medium is of the latter type.

As NRRO, vibration of a medium mounted on a spindle at the time of normal rotation can be measured by a noncontact sensor. At this time, in NRRO, there are an NRRO component caused from a medium and an NRRO component caused from a spindle motor. By measuring NRRO of a plurality of media manufactured under the same conditions using the same spindle motor, evaluation is performed excluding the NRRO component caused from the spindle motor.

### Example 1 (Relationship Between Film Thickness of Stacked Film and Substrate Elastic Modulus)

In Example 1, an influence of an elastic modulus of a substrate in a scratch test and an influence of a distance (film thickness) from a sample surface subjected to the scratch test to the substrate in the scratch test are observed.

A 2.5-inch aluminum substrate was used as the substrate. Here, the aluminum substrate is a substrate that has a NiP layer formed on the surface of an aluminum plate by plating. Hereafter, the plated layer is expressed as a NiP plated layer and the aluminum substrate including the NiP plated layer is referred to as a substrate. An elastic modulus of the NiP plated layer can be controlled with the concentration of Ni and P in a plating solution, a temperature during plating, or the like. To confirm the elastic modulus of the substrate and crack resistance of a medium, an Young's modulus of the substrate was adjusted so that the Young's modulus of a first substrate (1) was 70 GPa, the Young's modulus of a second substrate (2) was 100 GPa, and the Young's modulus of a third substrate (3) was 134 GPa. The adjustment of the Young's modulus was performed at a Ni concentration of NiP plating and with a film thickness of a NiP plated layer. In the first substrate (1), a concentration of Ni:P was set to 88:12 and a film thickness was set to 50 nm. In the second substrate (2), a concentration of Ni:P was set to 92:8 and a film thickness was set to 10 μm. In the third substrate (3), a concentration of Ni:P was set to 98:2 and a film thickness was set to 10 μm. The second substrate (2) and the third substrate (3) were subjected to heat treatment at 400° C. for 1 hour.

Thereafter, a magnetic recording layer was formed on the obtained substrate.

First, a soft magnetic underlying layer (SUL) containing an alloy of FeCoTa formed to apply a strong magnetic field in a vertical direction to a recording layer to be described below was formed on each of the substrates with different indentation elastic moduli. An Young's modulus of the surface of the SUL layer was 120 GPa. To improve crystal orientation, a NiW underlying layer (UL) was further formed on the soft magnetic underlying layer. An Young's modulus of the NiW layer was 135 GPa. To control a magnetization direction of the recording layer in the vertical direction of the surface of the recording medium, an intermediate layer (IL) containing Ru was stacked on the underlying layer. An Young's modulus of the IL layer was 145 GPa.

Thereafter, Co₈₀Pt₂₀—SiO₂ was stacked as a magnetic recording layer (Mag layer) on the intermediate layer and a CoPt alloy layer which has no oxide to assist inversion of the magnetization of the recording layer was formed as a cap layer on the intermediate layer. An Young's modulus of the Mag layer was 136 GPa. Finally, a magnetic recording medium according to the embodiment was obtained by forming a protective film (not illustrated) by chemical vapor deposition (CVD) and applying a lubricant. The film thickness of each layer of the stacked layers included in the magnetic recording medium is shown in Table 1 below. A sample in which the film thicknesses are different as in Table 1 was manufactured. The sample was manufactured so that the film thickness of the Mag layer was constant and magnetostatic characteristics was not changed after the cap layer was formed, in order to evaluate crack resistance. The film thickness of each layer was adjusted so that the film thicknesses of the stacked layers were 40 nm, 60 nm, and 80 nm. In this adjustment, it can be understood that the magnetostatic characteristics measured by the magnetooptic Kerr effect are not considerably changed. The film thickness of each layer of the stacked films is summarized in Table 1 below.

TABLE 1

| | | Soft | | | | | |
|---|---|---|---|---|---|---|---|
| | | magnetic | | | Magnetic | | Total film |
| | | underlying | Underlying | Intermediate | recording | Cap layer | thickness |
| | | layer (nm) | layer (nm) | layer (nm) | layer (nm) | (nm) | (nm) |
| Stacked | (1) | 10 | 3 | 12 | 12 | 3 | 40 |
| layers | (2) | 20 | 5 | 20 | 12 | 3 | 60 |
| | (3) | 20 | 10 | 25 | 12 | 3 | 80 |

The indentation elastic moduli of the stacked films manufactured at the present time were measured using Tribo Indenter (TI950) made by Hysitron Inc. By setting the indentation depth to 20 nm using a Berkovich indenter, a composite elastic modulus of the films was measured using the Hertz theory. As a result, it can be understood that composite elastic moduli E_{film} of the samples are all 136 GPa.

A long-term reliability test for the stacked films was then performed.

As a result, a graph that indicates a relationship between a driving time (time) and an error rate (%) is illustrated in FIG. 5.

In the drawing, reference numeral 101 indicates the case of the first substrate (1) with a film thickness of 40 nm, reference numeral 102 indicates the case of the first substrate (1) with a film thickness of 80 nm, reference numeral 103 indicates the case of the second substrate (2) with a film thickness of 40 nm, reference numeral 104 indicates the case of the second substrate (2) with a film thickness of 80 nm, reference numeral 105 indicates the case of the third substrate (3) with a film thickness of 40 nm, and reference numeral 106 indicates the case of the third substrate (3) with a film thickness of 80 nm.

A sample of which an error rate of the long-term reliability test exceeds 1% may not be shipped because of its low yield percentage. In a test result of Example 1, it can be understood that the error rate exceeds 1% in the case of the first substrate (1) with a film thickness of 80 nm and the case of the second substrate (2) with a film thickness of 80 nm.

Next, a scratch test of each medium was performed using a spherical indenter with a radius of curvature of 1.5 μm.

It can be confirmed that when scratching was performing setting a load to 500 μN, a scratch with a depth of about 1.3 nm was formed and the strength of a signal was thus attenuated in the scratch portion. A result of a signal attenuation rate calculated at a ratio of an RMS value is shown in Table 2 below.

TABLE 2

| | Signal attenuation rate | | |
|---|---|---|---|
| | Film | Film | Film |
| | thickness | thickness | thickness |
| | of 40 nm | of 60 nm | of 80 nm |
| First | 0.03 | 0.1 | 0.15 |
| Substrate | | | |
| (1) | | | |
| Second | 0.085 | 0.19 | 0.26 |
| Substrate | | | |
| (2) | | | |
| Third | 0.16 | 0.31 | 0.4 |
| Substrate | | | |
| (3) | | | |

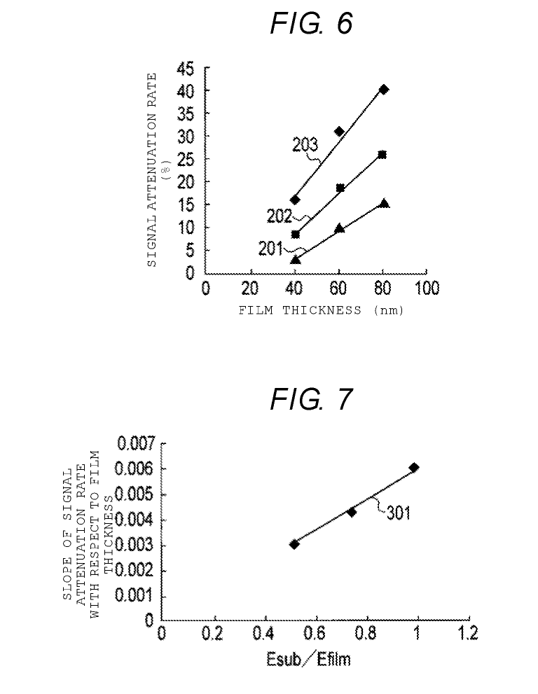

A graph indicating a relationship between a film thickness and a signal attenuation rate based on Table 2 is illustrated in FIG. 6.

In the drawing, reference numeral 201 indicates the case of the first substrate (1), reference numeral 202 indicates the case of second substrate (2), and reference numeral 203 indicates the case of third substrate (3).

When a percentage of a signal attenuation rates is converted into a ratio to obtain a linear functional equation of each graph, a graph 201 is y=0.003×−0.0867, a graph 202 is y=0.043×−0.818, and a graph 203 is y=0.006×−0.007.

A signal attenuation rate (ξ) has a positive correlation with a film thickness (h) of a film to be stacked is expressed in Equation (A).

ξ=ah (A)

Here, the variable ‘a’ indicates the slope of the signal attenuation rate in FIG. 6. The slopes ‘a’ of graphs 201, 202, and 203 are 0.003, 0.043, and 0.06, respectively.

Accordingly, a graph indicating a relationship between the slope ‘a’ of the signal attenuation rate with respect to a film thickness and an elastic modulus (GPa) of a substrate is illustrated in FIG. 7.

As indicated in a graph 301, it can be understood that the slope ‘a’ of a signal attenuation rate decreases as the elastic modulus of a substrate decreases.

In the drawing, the horizontal axis represents a ratio of E_{sub} to E_{film} and the vertical axis represents the slope ‘a’.

As a result, it can be understood that Equation (B) below is established between the slope ‘a’ of a signal attenuation rate and the elastic modulus of a substrate.

$$a = 0.006 * \frac{{E}_{sub}}{{E}_{film}} \qquad ( B )$$

The slope of a signal attenuation rate with respect to a film thickness has a positive correlation with a ratio of E_{sub} to E_{film}. Thus, it can be understood that as the value of an elastic modulus E_{sub} of a substrate decreases, the slope of a signal attenuation amount with respect to a film thickness decreases, and thus a medium with a strong crack resistance is obtained.

From the results of Equations (A) and (B), a signal attenuation rate ξ is expressed in Equation (C) below.

$$ξ = 0.006 * \frac{{E}_{sub}}{{E}_{film}} * h \qquad ( C )$$

As a result of a long-term reliability test, since an error rate exceeds 1% in the combination of the first substrate (1) and the film thickness of 80 and the combination of the second substrate (2) and the film thickness of 80, it is considered that such a sample has no crack resistance.

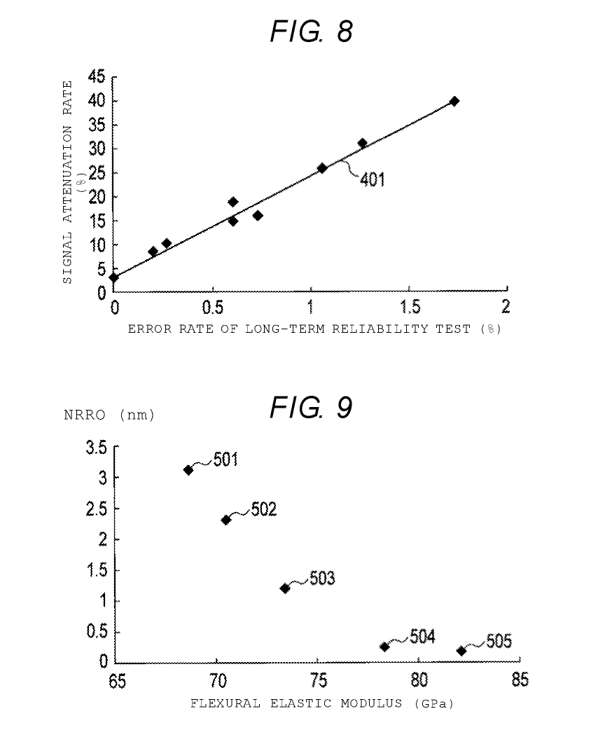

A graph indicating results of a long-term reliability test is illustrated in FIG. 8.

A graph 401 indicates a relationship between an error rate and a signal attenuation rate in a magnetic recording medium on which a long-term reliability test is conducted. From the graph 401, it can be understood that the signal attenuation rate should be equal to or less than 20% in order to observe no more than 1% error rate in the long-term reliability test.

When a restriction of ξ≤20% is added to Equation (C) above, Equation (D) can be expressed as follows.

$$ξ = 0.006 * \frac{{E}_{sub}}{{E}_{film}} * h \leq 0.2 \qquad ( D )$$

It can be understood that it is necessary for an elastic modulus E_{sub} of a substrate to satisfy Equation (E) below.

$${E}_{sub} \leq \frac{200 * {E}_{film}}{6 * h} \qquad ( E )$$

### Example 2

In order to use a substrate of a hard disk drive, it is necessary to reduce NRRO vibration (or NRRO for short), which is vibration that has no periodicity during rotation. It is understood that NRRO has correlation with flexural elasticity, and thus it is necessary for the flexural elastic modulus to be equal to or greater than at least 75 GPa. On the other hand, as described in Example 1, in order to reduce an error rate of a long-term reliability test, it is necessary to lower an Young's modulus of a substrate.

In this example, in view of the foregoing problem, a method of setting a flexural elastic modulus to 78 GPa and setting an Young's modulus to 70 GPa will be described as a specific method of achieving the first substrate (1).

First, an aluminum plate with 1.25 mm is used in a base material of a substrate to be used. In the aluminum plate, a flexural elastic modulus is 70.3 GPa and an Young's modulus is 69.7 GPa. To improve the flexural elastic modulus on the aluminum plate, a NiP layer is formed. To form the NiP layer, an electroless plating method using Top Nicoron BL made by Okuno Chemical Industries Co. LTD. is used.

A plated layer with a film thickness of 18 μm was formed by immersing the aluminum plate into a bath containing Top Nicoron BL in which a temperature was set to 80° C. and pH was adjusted to 12. It can be understood that a P concentration of the formed plated layer is about 2%. When the elastic modulus of a substrate in which the NiP plated layer was formed was measured, the flexural elastic modulus was 72.6 GPa and the Young's modulus was 114 GPa.

Thereafter, when the substrate in which the NiP plated layer is subjected to heat treatment at 600° C. for 1 hour, the flexural elastic modulus was 78.8 GPa and the Young's modulus was 148 GPa in regard to elastic moduli of the substrate.

Subsequently, a NiP plated layer of 2 μm was formed by controlling a temperature of a bath containing Top Nicoron BL to 80° C., controlling pH to 8.0, subsequently immersing the substrate subjected to heat treatment, and performing NiP plating again. In regard to elastic moduli of the obtained substrate, the flexural elastic modulus was 78.3 GPa and the Young's modulus was 68 GPa, and thus the Young's modulus was successfully reduced while maintaining the flexural elastic modulus equal to or greater than 75 GPa. A P concentration of a formed surface plated layer is about 12%.

By performing heat treatment at 600° C. again, it is possible to calculate 77 GPa of the flexural elastic modulus and 98 GPa of the Young's modulus.

A magnetic recording medium was manufactured by applying the condition that the film thickness is 80, as shown in Table 1 of Example 1, to a substrate which was not subjected to the heat treatment again and the Young's modulus was 68 GPa. From the result obtained by performing a scratch test on the magnetic recording medium, it can be understood that a signal attenuation rate obtained through MFM measurement is 14%. It can also be understood that NRRO at 5400 rpm is about 0.25 nm.

The obtained result is shown in Table 3.

### Example 3

In Example 3, an example in which the first substrate (1) is manufactured except the condition of Example 2 will be described below.

In a bath in which pH was controlled to 8.0 at 80° C., a plated layer of 5 μm was formed on the surface of the aluminum plate used in Example 2 in the substrate. In regard to elastic modulus of the obtained substrate, the flexural elastic modulus was 70.5 GPa and the Young's modulus was 68 GPa. A magnetic recording medium was manufactured by forming a recording layer on the substrate under the condition of the film thickness of 80 in Example 1. As a result obtained by performing a scratch test on the medium, the signal attenuation rate obtained through MFM measurement was about 13%. On the other hand, it can also be understood that NRRO at 5400 rpm is about 2.3 nm. A track pitch may not be reduced due to deterioration in NRRO, and thus recording density is decreased. Like the present case, when NRRO is 2.3 nm, for example, recording density of 386 kFCI is decreased to recording density of 367 kFCI, which represents about 5% deterioration.

The obtained result is shown in Table 3.

### Example 4

In Example 4, a long-term reliability test was performed using the same substrate as the substrate manufactured in Example 3.

As a result obtained by performing the long-term reliability test using 1450 drives, an error rate was 3.5%.

Since a signal attenuation rate in a scratch test is 13%, it is expected that an error rate of the long-term reliability test is equal to or less than 1%, but an actual error rate is high. A sample in which an Young's modulus was 70 GPa and a signal attenuation rate was about 15% in a scratch test was manufactured while changing a flexural elastic modulus as follows and a long-term reliability test was performed on each medium.

A1060 aluminum was used as a substrate (2-1) in which a flexural elastic modulus is 68.6 GPa.

A substrate (2-2) in which a flexural elastic modulus is 70.5 GPa is obtained in the same way as the substrate used in Example 3.

A substrate (2-3) in which a flexural elastic modulus is 73.4 GPa can be manufactured by baking the substrate used in Example 3 at 400° C. for 1 hour.

The same substrate as that used in Example 1 can be used as a substrate (2-4) in which a flexural elastic modulus is 78.3 GPa.

A substrate (2-5) in which a flexural elastic modulus is 82.1 GPa can be manufactured as in Example 1 except that a baking temperature is changed to 750° C.

The indentation elastic moduli of the substrates were all in the range from 68 GPa to 70 GPa.

Magnetic recording media were manufactured using the manufactured substrates as in Example 1 under the condition of the film thickness of 80 in Table 1 above.

FIG. 9 is a diagram illustrating a graph that indicates the NRRO observed during a long-term reliability test for a flexural elastic modulus of each of media (2-1), (2-2), (2-3), (2-4), and (2-5).

In the drawing, points 501, 502, 503, 504, and 505 indicate test results of the media (2-1), (2-2), (2-3), (2-4), and (2-5).

From FIG. 9, it can be understood that NRRO is changed linearly with respect to a flexural elastic modulus.

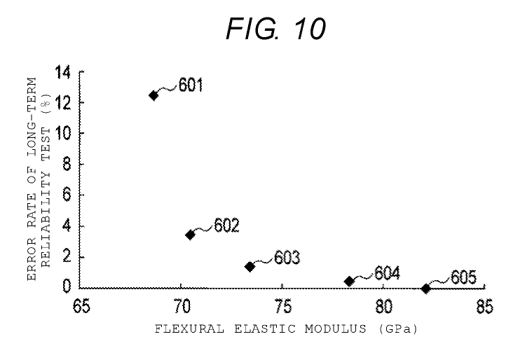

A result of an error rate of the long-term reliability test of the flexural elastic modulus in each of the media (2-1), (2-2), (2-3), (2-4), and (2-5) is illustrated in FIG. 10.

In the drawing, points 601, 602, 603, 604, and 605 indicate results of the media (2-1), (2-2), (2-3), (2-4), and (2-5), respectively.

An error rate in a long-term reliability test exponentially increases with a decrease in a flexural elastic modulus. It is considered that the reason for this is that contamination easily occurs between a substrate and a head with the decrease in the elastic modulus. From the foregoing result, a flexural elastic modulus is preferably equal to or greater than 75 GPa in order that the error rate in the long-term reliability test is equal to or less than 1%. In particular, the flexural elastic modulus is more preferably equal to or greater than 78 GPa.

The obtained result is shown in Table 3.

### Comparative Example 1

In Comparative Example 1, a scratch test and a long-term reliability test are performed on a substrate by changing a film thickness using the same substrates as that of Example 2 in which an Young's modulus is 68 GPa.

First, B is added to the soft magnetic underlying layer (SUL layer) of FeCoTa so that 10% of the layer is B, and the layer is formed to a thickness of 40 nm on the substrate. An Young's modulus of the SUL layer was 138 GPa. To improve crystal orientation on the SUL layer, a NiTa underlying layer (UL) is formed to a thickness of 15 nm. An elastic modulus of NiTa was 135 GPa. To control a magnetization direction of a recording layer in the vertical direction of the surface of a recording medium, an intermediate layer (IL) containing Ru having a thickness of 25 nm was stacked on the underlying layer. An Young's modulus of the IL layer was 145 GPa.

Thereafter, Co₈₀Pt₂₀—SiO₂ was stacked to a thickness of 13 nm as a magnetic recording layer (Mag) on the intermediate layer and a CoPt alloy layer which has no oxide to assist inversion of the magnetization of the recording layer was formed to a thickness of 2 nm as a cap layer on the recording layer. An Young's modulus of the Mag layer was 136 GPa. Finally, a magnetic recording medium according to the embodiment was obtained by forming a protective film (not illustrated) by 2 nm by chemical vapor deposition (CVD) and applying a lubricant.

A film thickness h formed on the substrate was 97 nm and the value of a composite elastic modulus of stacked films was 136 GPa. When calculation is performed using Equation (C), an attenuation rate of the medium was 29.1%. When a scratch test was performed, the attenuation rate was 30.2%, which is very close to the calculation result. In the long-term reliability test using 1300 drives, an error rate was 1.8%.

The obtained result is shown in Table 3.

### Comparative Example 2

In Comparative Example 2, a substrate with an Young's modulus of 148 GPa and thus higher than in Examples 1 to 4 and Comparative Example 1, was used. In manufacturing of a substrate, pH was set to 12 in the plating solution used in Example 2 and a plated layer of 20 μm was formed at 80° C. Thereafter, baking was performed at a high temperature of 600° C. for 1 hour and an elastic modulus is subsequently evaluated, until the flexural elastic modulus was 79.2 GPa and the Young's modulus was 148 GPa. Subsequently, each metal layer is formed on an obtained substrate. First, a SUL layer containing 10% of B, which was formed by adding B to FeCoTa, was formed to a thickness of 25 nm on the substrate. The Young's modulus of the SUL layer was 138 GPa. To improve crystal orientation on the soft magnetic underlying layer, a NiTa underlying layer (UL) is formed to a thickness of 5 nm. The elastic modulus of NiTa was 135 GPa. To control a magnetization direction of a recording layer in the vertical direction of the surface of a recording medium, an intermediate layer (IL) containing Ru having a thickness of 25 nm was stacked on the underlying layer. The Young's modulus of the IL layer was 145 GPa.

Thereafter, Co₈₀Pt₂₀—SiO₂ was stacked to a thickness of 13 nm as a magnetic recording layer (Mag) on the intermediate layer and a CoPt alloy layer which has no oxide to assist inversion of the magnetization of the recording layer was formed to a thickness of 2 nm as a cap layer on the intermediate layer. The Young's modulus of the Mag layer was 136 GPa. Finally, a magnetic recording medium according to the embodiment was obtained by forming a protective film (not illustrated) to a thickness of 2 nm by chemical vapor deposition (CVD) and applying a lubricant.

A film thickness h formed on the substrate was 72 nm and the value of the composite elastic modulus of stacked films was 136 GPa. When calculation is performed using Equation (C), the attenuation rate of the medium was 47.0%. When a scratch test was performed, the attenuation rate was 39.5%, which is slightly worse than the calculation result. In the long-term reliability test using 1300 drives, the error rate was 2.2%.

The obtained result is shown in Table 3.

TABLE 3

| | Substrate | | | | | | | | |
|---|---|---|---|---|---|---|---|---|---|
| | Flexural | | | | | | | | |
| | elastic | | Stacked film | | | | | Error | |
| | modulus | E_{sub} | h | E_{film} | (200 * E_{film})/ | Fit to Equation | Attenuation | rate | NRRO |
| | (GPa) | (GPa) | (nm) | (GPa) | 6 h | (1) | rate (%) | (%) | (nm) |
| Example 2 | 75.0 | 68.0 | 80 | 136 | 113 | ◯ | 14 | — | 0.25 |
| Example 3 | 70.5 | 68.0 | 80 | 136 | 113 | ◯ | 13 | — | 2.3 |
| Example 4 | 68.6 | 70.0 | 80 | 136 | 113 | ◯ | 15 | 3.5 | — |
| Comparative | 75.0 | 68.0 | 97 | 136 | 46.74 | X | 29.1 | 1.8 | — |
| Example 1 | | | | | | | | | |
| Comparative | 79.2 | 148 | 72 | 136 | 62.96 | X | 39.5 | 2.2 | — |
| Example 2 | | | | | | | | | |

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic recording medium comprising:
a substrate; and
a stacked film on the substrate and including a magnetic recording layer,
wherein an elastic modulus E_{sub} of the substrate satisfies Equation (1) below, where h is a film thickness of the stacked film and E_{film} is an Young's modulus of the stacked film,
E_{sub}≤(200*E_{film})/(6*h) (1).

2. The magnetic recording medium according to claim 1,
wherein the substrate has a flexural elastic modulus equal to or greater than 75 GPa.

3. The magnetic recording medium according to claim 2,
wherein the substrate includes a base material and an alloy layer formed on the base material.

4. The magnetic recording medium according to claim 3,
wherein the alloy layer has a multilayer structure that includes a first plated layer formed on the substrate and a second plated layer formed on the first plated layer.

5. The magnetic recording medium according to claim 4,
wherein the first plated layer has a flexural elastic modulus equal to or greater than 78 GPa.

6. The magnetic recording medium according to claim 1, wherein the substrate includes an aluminum base layer and an NiP layer on the aluminum base layer, and the stacked film includes intermediate layers between the magnetic recording layer and the substrate.

7. The magnetic recording medium according to claim 6, wherein the intermediate layers include a FeCoTa layer on the substrate, a NiW layer on the FeCoTa layer, and a Ru layer on the NiW layer.

8. The magnetic recording medium according to claim 7, wherein the magnetic recording layer is directly in contact with the Ru layer and contains Co₈₀Pt₂₀—SiO₂.

9. A method of forming a magnetic recording medium, comprising:
forming a stacked film including a magnetic recording layer on a substrate having an elastic modulus E_{sub},
wherein the stacked film is formed to a film thickness of h and to have an Young's modulus E_{film} such that E_{sub}≤(200*E_{film})/(6*h).

10. The method according to claim 9,
wherein the substrate has a flexural elastic modulus equal to or greater than 75 GPa.

11. The method according to claim 10,
wherein the substrate includes a base material and an alloy layer formed on the base material.

12. The method according to claim 11,
wherein the alloy layer has a multilayer structure that includes a first plated layer formed on the substrate and a second plated layer formed on the first plated layer.

13. The method according to claim 12,
wherein the first plated layer has a flexural elastic modulus equal to or greater than 78 GPa.

14. The method according to claim 9, wherein the substrate includes an aluminum base layer and an NiP layer on the aluminum base layer, and the stacked film includes intermediate layers between the magnetic recording layer and the substrate.

15. The method according to claim 14, wherein the intermediate layers include a FeCoTa layer on the substrate, a NiW layer on the FeCoTa layer, and a Ru layer on the NiW layer.

16. The method according to claim 15, wherein the magnetic recording layer is directly in contact with the Ru layer and contains Co₈₀Pt₂₀—SiO₂.
